(19) United States
(12) Patent Application Publication
(10) Pub. No.: US 2025/0149794 A1
(43) Pub. Date: May 8, 2025

(54) Versatile Resonator Radiator for Phased Array Applications

(71) Applicant: International Business Machines Corporation, Armonk, NY (US)

(72) Inventors: Duixian Liu, Scarsdale, NY (US); Alberto Valdes Garcia, Chappaqua, NY (US); Christian Wilhelmus Baks, Peasant Valley, NY (US)

(21) Appl. No.: 18/387,128

(22) Filed: Nov. 6, 2023

(51) Int. Cl. H01Q 9/04; H01L 23/66; H01P 7/06; H01Q 1/22; H01Q 1/42; H01Q 3/36; H01Q 21/00

(52) U.S. Cl. CPC H01Q 9/0485; H01L 23/66; H01Q 1/2283; H01Q 1/422; H01Q 3/36; H01Q 21/0087; H01L 2223/6616; H01L 2223/6627; H01L 2223/6677; H01P 7/065

(57) ABSTRACT

Scalable and easily manufactured cavity resonator radiator arrays for millimeter wave or terahertz phased array antenna applications are provided. In one aspect, an antenna device includes: a first component including a substrate having antenna feedlines within a first dielectric and a ground plane disposed on the first dielectric; a second component, coupled to the first component, including a metallic grid having a plurality of cavities filled with a second dielectric to provide an array of cavity resonator radiators, where the ground plane includes aperture slots between the antenna feedlines and the cavity resonator radiators. The antenna feedlines can include first and second antenna feedlines for dual-polarization, located in different layers, for enhanced port isolation. A method of forming an antenna device is also provided where the metallic grid having the plurality of cavities filled with the second dielectric can be formed using 3D printing, metal stamping and/or laser cutting.

### FIELD OF THE INVENTION

The present invention relates to phased array antenna designs, and more particularly, to scalable and easily manufactured cavity resonator radiator arrays for millimeter wave or terahertz phased array antenna applications.

### BACKGROUND OF THE INVENTION

With wireless signal propagation, phased antenna arrays are used for beamforming in a variety of different high-frequency applications to transmit signals in a specific direction. For instance, beamforming techniques are employed in wireless communications networks like fifth-generation technology standard cellular networks which require high data transmission rates to ensure maximum transmit and receive efficiency.

To date, phased antenna array designs having these high-frequency capabilities require complex and intricate multistep schemes to produce them. Implementing these processes undesirably increases manufacturing costs and reduces overall throughput.

### SUMMARY OF THE INVENTION

The present invention provides scalable and easily manufactured cavity resonator radiator arrays for millimeter wave or terahertz phased array antenna applications. In one aspect of the invention, an antenna device is provided. The antenna device includes: a first component including a substrate having antenna feedlines within a first dielectric, and a ground plane disposed on the first dielectric; a second component, coupled to the first component, including a metallic grid having a plurality of cavities filled with a second dielectric to provide an array of cavity resonator radiators for the antenna device, where the ground plane includes aperture slots between the antenna feedlines and the cavity resonator radiators.

The first dielectric and the second dielectric can be different materials with different dielectric constants. For example, the first dielectric can have a first dielectric constant κ₁ and the second dielectric can have a second dielectric constant κ₂, where the first dielectric constant κ₁ can be different from the second dielectric constant κ₂.

Preferably, the cavities have a square or approximately square shape. For instance, embodiments are contemplated herein where the cavities have a rectangular shape with sides of length a and b, and wherein a≈b including the case where a=b.

Advantageously, filling the cavities of the metallic grid with dielectric enables the size of the cavity resonator radiator to be scaled, for example, to a λ/2 spacing as required to form a phased array. Further, employing separate first and second components in the design helps streamline the fabrication process. For instance, three-dimensional (3D) printing or other low-complexity manufacturing methods like metal stamping or laser cutting may be used in producing the present antenna device. Alternatively, embodiments are contemplated herein where the metallic grid of the present antenna device is formed from a plurality of metal through vias in the second dielectric arranged side-by-side in a grid pattern.

In another aspect of the invention, another antenna device is provided. The antenna device includes: a first component including a substrate having antenna feedlines within a first dielectric and a ground plane comprising aperture slots disposed on the first dielectric; a second component, coupled to the first component, including a metallic grid having a plurality of cavities filled with a second dielectric to provide an array of cavity resonator radiators for the antenna device, where the antenna feedlines include first antenna feedlines and second antenna feedlines for dual-polarization, and where the first antenna feedlines and the second antenna feedlines are located in different layers.

For instance, the first antenna feedlines can be located above the aperture slots, and the second antenna feedlines can be located below the aperture slots. Doing so advantageously separates the first and second (e.g., vertical and horizontal polarization, or vice versa) antenna feedlines from one another in order to enhance port isolation.

In yet another aspect of the invention, a method of forming an antenna device is provided. The method includes: forming a first component including a substrate having antenna feedlines within a first dielectric, and a ground plane having aperture slots disposed on the first dielectric; forming a second component including a metallic grid having a plurality of cavities filled with a second dielectric to provide an array of cavity resonator radiators; and joining the first component to the second component such that the aperture slots are present between the antenna feedlines and the cavity resonator radiators to form the antenna device.

As provided above, forming the first component separately from the second component advantageously allows low-complexity manufacturing methods to be employed. For example, the metallic grid having the plurality of cavities filled with the second dielectric can be formed using a process selected from: 3D printing, metal stamping, laser cutting, and combinations thereof. For instance, embodiments are contemplated herein where the metallic grid having the plurality of cavities filled with the second dielectric is formed using mixed metal and dielectric 3D printing.

A more complete understanding of the present invention, as well as further features and advantages of the present invention, will be obtained by reference to the following detailed description and drawings.

### BRIEF DESCRIPTION OF THE DRAWINGS

FIG. 1 is a cross-sectional diagram illustrating a phased array antenna device having a dielectric filled metallic grid forming multiple cavity resonator radiators according to an embodiment of the present invention;

FIG. 2 is a top-down diagram of the dielectric filled metallic grid of FIG. 1 according to an embodiment of the present invention;

FIG. 3 is a cross-sectional diagram illustrating the metallic grid and dielectric fill having been co-fabricated using mixed metal and dielectric three-dimensional (3D) printing according to an embodiment of the present invention;

FIG. 4 is a top-down diagram of the metallic grid and dielectric fill of FIG. 3 having been co-fabricated using mixed metal and dielectric 3D printing according to an embodiment of the present invention;

FIG. 5 is a cross-sectional diagram illustrating the metallic grid and dielectric fill having been fabricated separately and then assembled together according to an embodiment of the present invention;

FIG. 6 is a top-down diagram of the metallic grid and dielectric fill of FIG. 5 having been fabricated separately and then assembled together according to an embodiment of the present invention;

FIG. 7 is a diagram illustrating an exemplary methodology for forming the present phased array antenna device according to an embodiment of the present invention;

FIG. 8 is a cross-sectional diagram (A-A′) illustrating the present cavity resonator radiator for a single-polarization antenna according to an embodiment of the present invention;

FIG. 9 is a top-down diagram of the cavity resonator radiator of FIG. 8 for a single-polarization antenna according to an embodiment of the present invention;

FIG. 10 is a cross-sectional diagram (B-B′, see FIG. 12) illustrating the present cavity resonator radiator for a dual-polarization antenna according to an embodiment of the present invention;

FIG. 11 is a cross-sectional diagram (C-C′, see FIG. 12) illustrating the present cavity resonator radiator for a dual-polarization antenna according to an embodiment of the present invention;

FIG. 12 is a top-down diagram of the cavity resonator radiator of FIGS. 10 and 11 for a dual-polarization antenna according to an embodiment of the present invention;

FIG. 13 is a cross-sectional diagram (D-D′, see FIG. 15) illustrating the present cavity resonator radiator for a dual-polarization antenna having the antenna feedlines in different layers according to an embodiment of the present invention;

FIG. 14 is a cross-sectional diagram (E-E′, see FIG. 15) illustrating the present cavity resonator radiator for a dual-polarization antenna having the antenna feedlines in different layers according to an embodiment of the present invention;

FIG. 15 is a top-down diagram of the cavity resonator radiator of FIGS. 13 and 14 for a dual-polarization antenna having the antenna feedlines in different layers according to an embodiment of the present invention;

FIG. 16 is a three-dimensional diagram illustrating the present cavity resonator radiator for a dual-polarization antenna having the antenna feedlines in different layers according to an embodiment of the present invention;

FIG. 17 is a diagram illustrating an arrangement of unit cells implemented as a two-dimensional array according to an embodiment of the present invention;

FIG. 18 is a diagram illustrating a phased array antenna device having a wafer with through-vias according to an embodiment of the present invention;

FIG. 19 is a cross-sectional diagram illustrating the present dielectric filled metallic grid formed from a plurality of metal through vias arranged side-by-side in a grid pattern according to an embodiment of the present invention;

FIG. 20 is a top-down diagram of the present dielectric filled metallic grid of FIG. 19 formed from a plurality of metal through vias arranged side-by-side in a grid pattern according to an embodiment of the present invention;

FIG. 21 is a three-dimensional diagram illustrating an example of the present cavity resonator radiator having a single aperture slot according to an embodiment of the present invention;

FIG. 22 is a three-dimensional diagram illustrating an example of the present cavity resonator radiator having aperture slots that intersect one another according to an embodiment of the present invention; and

FIG. 23 is a three-dimensional diagram illustrating an example of the present cavity resonator radiator having aperture slots that are spaced apart from one another and do not intersect according to an embodiment of the present invention.

### DETAILED DESCRIPTION OF PREFERRED EMBODIMENTS

As described above, phased antenna array designs compatible with high-frequency applications often require complex, multistep processes for production, thereby increasing manufacturing costs and lowering overall throughput. Advantageously, provided herein are low-cost phased array antenna package designs and techniques for fabrication thereof for millimeter wave (mm Wave) or Terahertz (THz) applications, e.g., applications operating at a frequency of 20 gigahertz (GHz) and higher. For instance, as will be described in detail below, embodiments are contemplated herein where the present antenna designs are realized through the use of three-dimensional (3D) printing or other comparable low-complexity manufacturing methods like metal stamping or laser cutting.

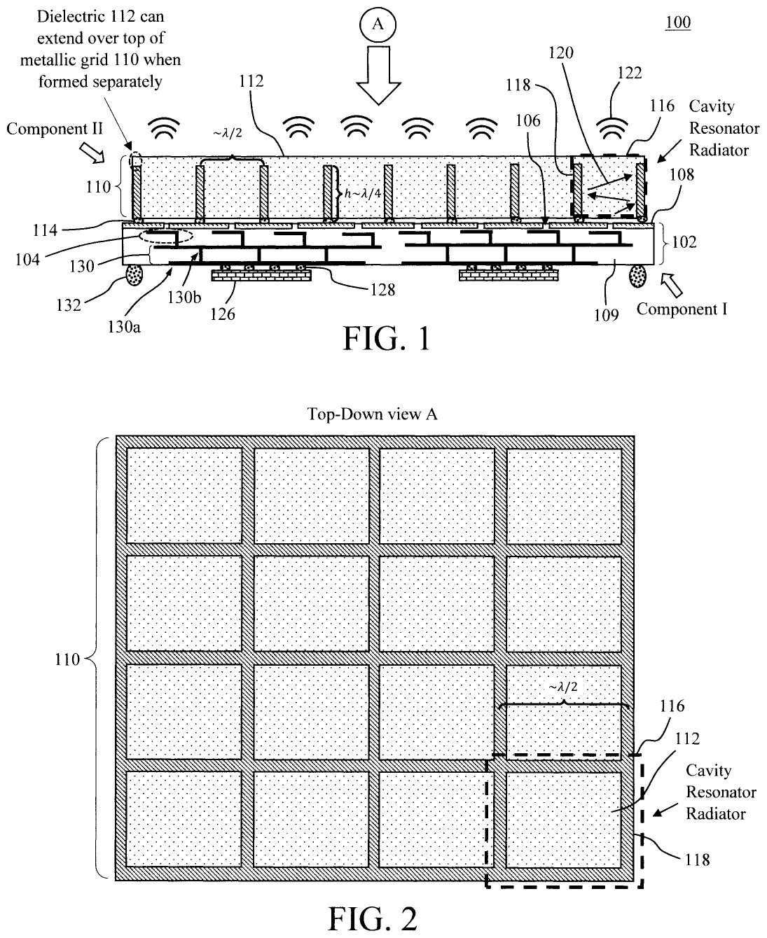

For instance, a phased array antenna device 100 in accordance with the present techniques is presented in FIG. 1. As shown in FIG. 1, phased array antenna device 100 includes a substrate 102 having antenna feedlines 104 within a dielectric 109, and a ground plane 108 disposed on the dielectric 109, and a metallic grid 110 (filled with a dielectric 112) disposed on the substrate 102 and connected to the ground plane 108 via, e.g., solder bumps 114. Aperture slots 106 corresponding to the antenna feedlines 104 are present in the ground plane 108. The metallic grid 110 includes a plurality of approximately square cavities filled with the dielectric 112 forming an array of cavity resonator radiators between individual (antenna) elements 118 of the metallic grid 110, as indicated by dashed box 116. Namely, the dielectric 112 is used to reduce resonator size for radio waves that bounce back and forth between individual elements 118 of the metallic grid 110 (see arrows 120) to form a standing wave which, as indicated by graphic 122, is then radiated into space. The antenna feedlines 104 and the cavity resonator radiators together form an antenna. As shown in FIG. 1, the aperture slots 106 in ground plane 108 are present between the antenna feedlines 104 and the cavity resonator radiators. As will be described in detail below, there is at least one aperture slot 106 in the ground plane 108 for each of the cavity resonator radiators.

Advantageously, as shown in FIG. 1, filling the metallic grid 110 with the dielectric 112 enables the size of the cavity resonator radiator to be reduced, i.e., scaled, such that the elements 118 of the metallic grid 110 can be placed at about a λ/2 spacing, as required to form a phased array. Here, Δ is the center frequency of the waveform being transmitted or received. Thus, λ/2 is a half-wavelength spacing. Further, according to an exemplary embodiment, each element 118 of the metallic grid 110 has a height h of about λ/4 (i.e., quarter wavelength).

As their name implies, the antenna feedlines 104 provide or ‘feed’ a signal to/from at least one signal port, in this case beamforming integrated circuits 126, from/to the cavity resonator radiators via the aperture slots 106 in ground plane 108 to form an active phased array.

When used as a signal source, beamforming integrated circuits 126 (such as radio frequency integrated circuits) can regulate the phase of the signal that is sent to the cavity resonator radiators. In the example depicted in FIG. 1, beamforming integrated circuits 126 are coupled, i.e., connected, to the antenna feedlines 104 via solder bumps 128. The present antenna array itself is a passive reciprocal device. When coupled to an active integrated circuit (such as beamforming integrated circuits 126), it can then become a phased array transmitter, receiver, or transceiver (depending on the integrated circuit functionality).

Substrate 102 includes the antenna feedlines 104 contained within dielectric 109, and ground plane 108 disposed on the dielectric 109. For clarity, the terms ‘first’ and ‘second’ may be used herein when referring to dielectric 109 and dielectric 112, respectively. According to an exemplary embodiment, (first) dielectric 109 has a first dielectric constant κ₁ and (second) dielectric 112 has a second dielectric constant κ₂, where the first dielectric constant κ₁ can be different from the second dielectric constant κ₂, i.e., K₁≠K₂. In general, the dielectric constant κ of a material is typically expressed as a ratio of the electric permittivity of the material E to the electric permittivity of a vacuum ε₀. i.e.,

$$κ = \frac{ε}{{ε}_{0}} .$$

Advantageously, the use of two different (first/second) dielectrics provides manufacturability and design flexibility. According to an exemplary embodiment, antenna feedlines 104 and ground plane 108 are each formed from a metal such as, but not limited to, copper (Cu), nickel (Ni), platinum (Pt), tungsten (W) and/or gold (Au).

As shown in FIG. 1, substrate 102 containing the antenna feedlines 104 and ground plane 108 can be implemented as a redistribution layer for integrated circuit packaging, such as a redistribution layer 130 for integrated circuits 126 containing metal lines 130a and vias 130b. Alternatively, embodiments are contemplated herein where substrate 102 containing the antenna feedlines 104 and ground plane 108 is implemented as a stand-alone, structurally rigid substrate, such as a printed circuit board. In either case, the substrate 102 containing the antenna feedlines 104 and ground plane 108 is a separate and distinct component of the present design from the dielectric 112 filled metallic grid 110. Namely, as will be described in detail below, the substrate 102 containing the antenna feedlines 104 within dielectric 109, and ground plane 108 with aperture slots 106 disposed on dielectric 109 (Component I) is fabricated separately from the dielectric 112 filled metallic grid 110 (Component II). The two components, Component I and Component II, are then joined together (i.e., coupled) via, e.g., solder bumps 114. To look at it another way, as shown in FIG. 1 the antenna feedlines 104 and ground plane 108 are located solely in the substrate 102 and are wholly separate from the dielectric 112 filled metallic grid 110, and vice versa. As will be described in detail below, implementing this separate component packaging design advantageously enables unique and low-cost manufacturing methods such as 3D printing, metal stamping and/or laser cutting to be used as a low-complexity approach during fabrication. Optionally, this package (Component I and Component II, along with integrated circuits 126) can be attached to a larger substrate such as an application board (not shown) via, e.g., solder bumps 132.

Notably, once Component I and Component II are joined together, the metallic grid 110 is coupled to the antenna feedlines 104 through the aperture slots 106 in ground plane 108. Namely, as shown in FIG. 1, there is one antenna feedline 104 for each corresponding aperture slot 106 and cavity resonator radiator. As will be described in detail below, embodiments are contemplated herein having a single-polarization with one aperture slot 106 for each cavity resonator radiator, or others having dual-polarization with multiple (e.g., perpendicular) aperture slots 106 for each cavity resonator radiator.

FIG. 2 is a top-down diagram from viewpoint A (see FIG. 1) illustrating the dielectric 112 filled metallic grid 110 from a top-down view (see viewpoint A in FIG. 1). Like structures are numbered alike throughout the figures. As will be described in detail below, when these structures are formed separately, portions of the dielectric 112 can extend over the top of (and obscure from a top-down view) the underlying metallic grid 110. See FIG. 1. However, for ease and clarity of depiction, those overhanging portions of the dielectric 112 are not made visible in FIG. 2 in order to show the metallic grid 110 design.

As shown in FIG. 2, the metallic grid 110 is made up of multiple square, or approximately square, cavities arranged in a grid pattern, each of which is filled with the dielectric 112 forming a cavity resonator radiator between individual (antenna) elements 118 of the metallic grid 110, as indicated by dashed box 116. In this particular example, the grid pattern contains an equal number of cavities in each row and column, in this case forming a 4×4 grid. Of course, the number of cavities in the metallic grid 110 can vary depending on the particular application at hand, with a larger grid containing more cavities than shown, and vice versa. Further, other grid patterns are contemplated herein, such as those with an unequal number of cavities in each row and column, e.g., a 2×4 grid, a 3×4 grid, etc.

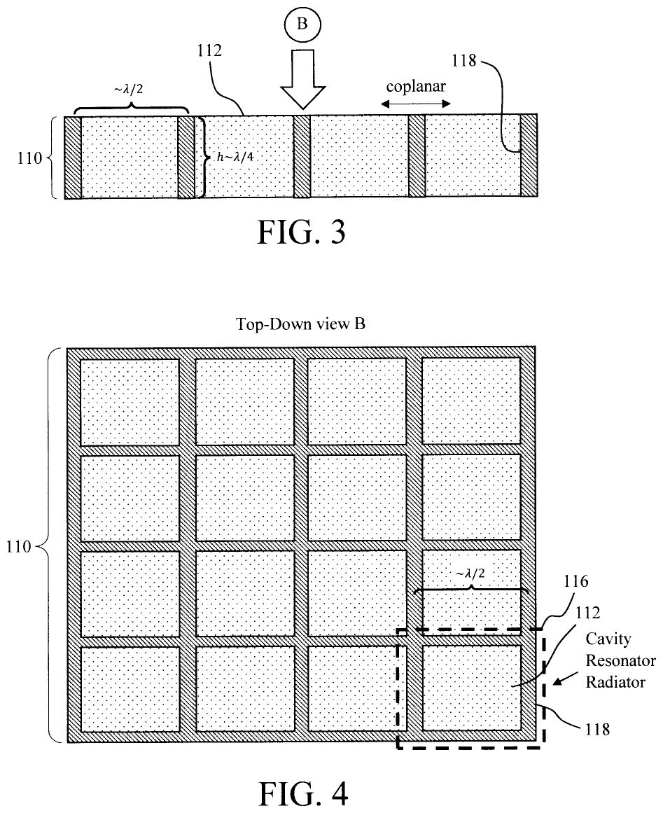

As highlighted above, a goal of the present techniques is to provide a design that can be realized using low-complexity manufacturing methods such as 3D printing, metal stamping and/or laser cutting in an effort to lower manufacturing costs and increase overall throughput. In that regard, embodiments are contemplated herein where at least a portion of the dielectric 112 filled metallic grid 110 fabrication is performed using 3D printing. For instance, referring to a first example shown in FIG. 3 (a cross-sectional view) and FIG. 4 (a top-down view from viewpoint B in FIG. 3), mixed metal and dielectric 3D printing is implemented to co-fabricate the metallic grid 110 and dielectric 112 fill.

Generally, 3D printing is a computer-controlled printing process that can be used to create three-dimensional structures from a variety of materials such as plastics, metals, etc. A 3D printer deposits the appropriate material(s) by an additive process that builds the structure up layer-by-layer. Regarding metals, printing of a single metal or a combination of metals (i.e., metal alloys) may be performed using metal powders as the raw materials which are then melted or otherwise fused together during the printing process to form the 3D structures layer-by-layer. For use in a similar manner, 3D printing dielectric resins are also commercially available.

In order to co-fabricate the metallic grid 110 and dielectric 112 fill by 3D printing, meaning that the metallic grid 110 and dielectric 112 fill are printed together (a process referred to herein as ‘mixed metal and dielectric 3D printing’), a hybrid 3D printer is needed which can print more than one material in a given printing session such as a metal for one part of the structure (in this case metallic grid 110) and a dielectric for another (in this case dielectric 112). For instance, hybrid 3D printers are available which enable the printing of more than one material using multiple nozzles to dispense each of the raw materials during the printing session.

By way of example only, metals that can be used in accordance with the present techniques for printing metallic grid 110 include, but are not limited to, aluminum (Al), steel, stainless steel, titanium (Ti), tantalum (Ta) and/or tungsten (W). Commercially available 3D printing dielectric resins that can be used in accordance with the present techniques for printing dielectric 112 include, but are not limited to, ceramic filled polymers that are ultraviolet light curable.

As shown in FIG. 3, using mixed metal and dielectric 3D printing to co-fabricate the metallic grid 110 and dielectric 112 fill can result in a top surface of the metallic grid 110 being coplanar with a top surface of the dielectric 112. In that case, no portion of the dielectric 112 will obscure the underlying the metallic grid 110 when viewed from the top-down. See, for example, FIG. 4.

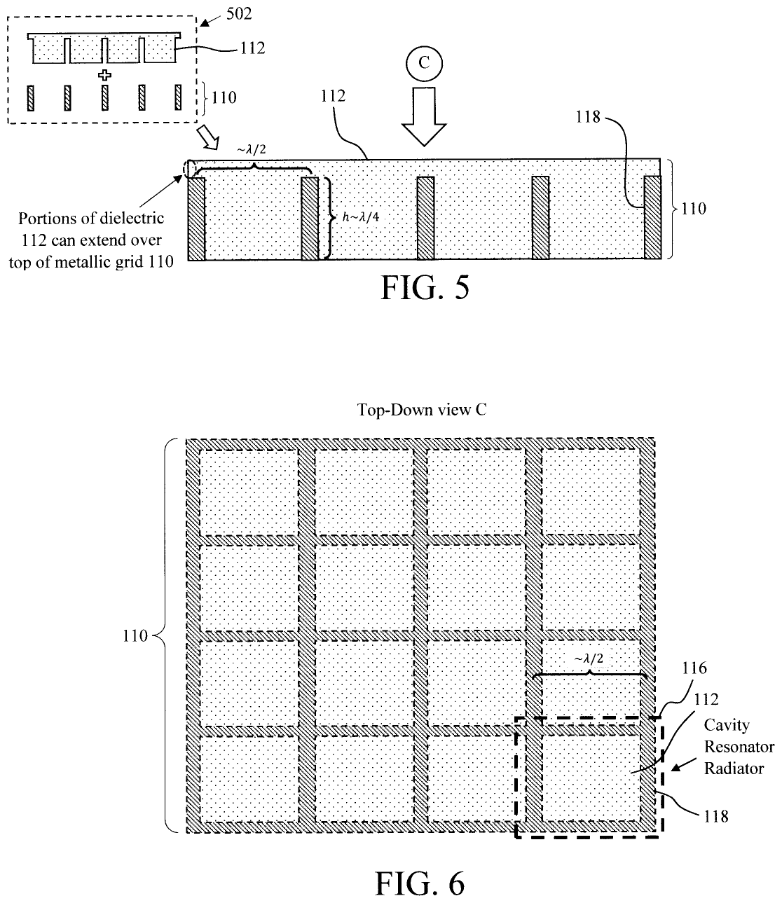

Alternatively, in a second example shown in FIG. 5 (a cross-sectional view) and FIG. 6 (a top-down view from viewpoint C in FIG. 5), the metallic grid 110 and dielectric 112 fill are fabricated separately, and then assembled together. While this alternative approach adds an additional assembly step, it also provides some notable advantages. For instance, printing a single material, i.e., metal and dielectric separately, requires less complex, and thus less costly 3D printing equipment. Also, fabricating the metallic grid 110 and dielectric 112 fill separately enables the integration of other low-complexity manufacturing techniques into the process flow, thus providing more options. For example, embodiments are contemplated herein where the metallic grid 110 is manufactured using one process or combination of processes such as metal stamping and/or laser cutting, and the dielectric 112 fill is manufactured using another different process such as 3D printing. As its name implies, metal stamping involves creating structures of a given shape out of a starting metal sheet by stamping. Similarly, laser cutting uses a laser beam to cut structures of a given shape out of a starting metal piece.

An example of separately fabricating the metallic grid 110 and dielectric 112 fill is illustrated in inset 502 of FIG. 5. Here, the dielectric 112 is formed by a process such as 3D printing. The metallic grid 110 is formed separately from the dielectric 110 also using a 3D printing process or, alternatively, by another process such as metal stamping or laser cutting. The two, separate parts are then assembled together to form the dielectric 112 filled metallic grid 110 shown in FIG. 5 and FIG. 6.

As highlighted above, fabricating the metallic grid 110 separate from the dielectric 112 can, once assembled, results in portions of the dielectric 112 extending over the top of the metallic grid 110. See FIG. 5. In that case, as shown in FIG. 5, dielectric 112 is present along the entire top surface of Component II, and obscures the underlying metallic grid 110 from a top-down view. Accordingly, the outline of the metallic grid 110 is shown with dashes in FIG. 6 so as to indicate that the metallic grid 110 is in fact covered by dielectric 112.

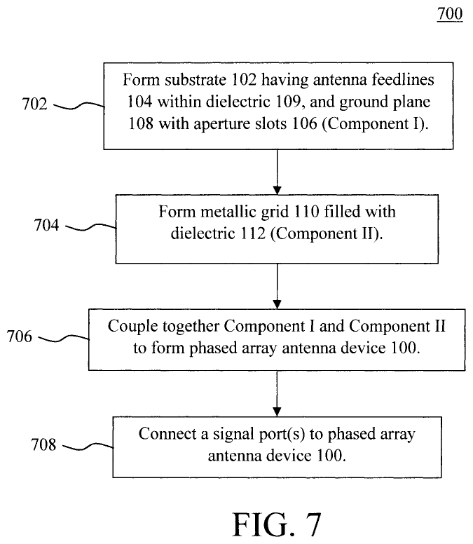

FIG. 7 is a diagram illustrating an exemplary methodology 700 for forming the present phased array antenna device 100. In step 702, the substrate 102 is formed having antenna feedlines 104 within dielectric 109, and ground plane 108 with aperture slots 106 disposed on the dielectric 109 (Component I). Standard metallization processes can be employed. As provided above, suitable metals for the antenna feedlines 104 and ground plane 108 include, but are not limited to, Cu, Ni, Pt, W and/or Au. As highlighted above, dielectric 109 can be a material having a different dielectric constant κ from dielectric 112. For ease of manufacturing, the preferred embodiment shown in FIG. 7 involves forming the ground plane 108 with aperture slots 106 as part of the substrate 102. However, although not shown, embodiments are also contemplated herein where the ground plane 108 with aperture slots 106 is instead formed as part of the metallic grid 110.

Antenna feedlines 104 have corresponding aperture slots 106 in the ground plane 108. There is at least one aperture slot 106 for each cavity resonator radiator. When there is one aperture slot for each cavity resonator radiator, the antenna is a single-polarization antenna. Alternatively, when there are multiple (e.g., horizontal and vertical polarization) aperture slots and antenna feedlines for each cavity resonator radiator, the antenna is a dual-polarization antenna. It is through these aperture slots that signals are fed from the antenna feedlines 104 to the cavity resonator radiators to form an active phased array.

In step 704, the dielectric 112 filled metallic grid 110 (Component II) is formed, separately from the substrate 102 having antenna feedlines 104 within dielectric 109, and ground plane 108 with aperture slots 106 disposed on the dielectric 109 (Component I). As provided above, embodiments are contemplated herein where the dielectric 112 filled metallic grid 110 are fabricated using 3D printing and/or other comparable low-complexity manufacturing methods like metal stamping or laser cutting. For instance, in one embodiment, the metallic grid 110 and dielectric 112 fill are co-fabricated using mixed metal and dielectric three-dimensional (3D) printing. Alternatively, in other embodiments, the dielectric 112 is formed by a process such as 3D printing. The metallic grid 110 is formed separately from the dielectric 110 also using a 3D printing process or, alternatively, by another process such as metal stamping or laser cutting. Forming the metallic grid 110 separately from the dielectric 112 simplifies the fabrication process by printing a single material, and gives the option of hybrid approaches, e.g., 3D printing and metal stamping or laser cutting.

As provided above, suitable metals for the metallic grid 110 include, but are not limited to, Al, steel, stainless steel, Ti, Ta and/or W. Dielectric 112 is a material having a different dielectric constant κ from dielectric 109. The dielectric 112 filled metallic grid 110 now includes a plurality of approximately square cavities, each of which forms a cavity resonator radiator between the individual (antenna) elements 118 of the metallic grid 110.

In step 706, the substrate 102 having antenna feedlines 104 within dielectric 109 and ground plane 108 with aperture slots 106 disposed on the dielectric 109 (Component I) and the dielectric 112 filled metallic grid 110 (Component II) are then joined together, i.e., coupled, to form phased array antenna device 100. As highlighted above, Component I and Component II are joined together in such a manner that the aperture slots 106 are present between the antenna feedlines 104 and the cavity resonator radiators (i.e., with at least one of the aperture slots 106 for each of the cavity resonator radiators). According to an exemplary embodiment, Component I and Component II are joined via solder bumps 114 directly connecting the ground plane 108 to the metallic grid 110.

In step 708, at least one signal port is then connected to the phased array antenna device 100. The antenna feedlines 104 will feed signals to/from (receive/transmit) the at least one signal port to the cavity resonator radiators via the aperture slot 106 in the ground plane 108. For instance, according to an exemplary embodiment, the substrate 102 containing the antenna feedlines 104 and ground plane 108 is implemented as a redistribution layer for integrated circuit packaging, and at least one beamforming integrated circuit 126 (e.g., a radio frequency integrated circuit as a signal port) is joined via solder bumps 128 directly to the redistribution layer 130.

It is notable that the steps of methodology 700 need not be performed in the order shown/described. What is important is that the Component I (i.e., substrate 102 having antenna feedlines 104 within the dielectric 109 and ground plane 108 with aperture slots 106 disposed on the dielectric 109) and Component II (i.e., metallic grid 110 having cavities filled with dielectric 112) are fabricated separately, and then joined together/coupled as described above. Thus, Component II can instead be fabricated prior to Component I, or both Component I and Component II can be simultaneously fabricated, just separately.

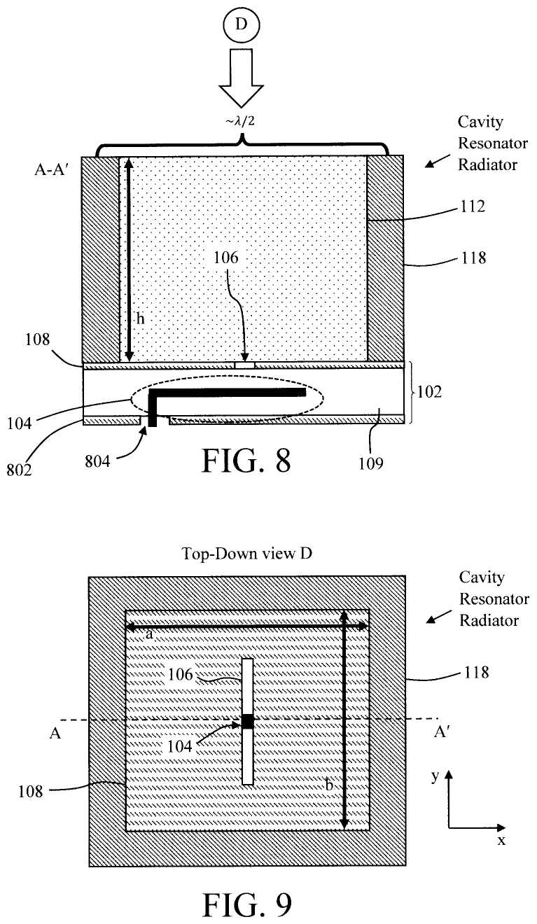

As highlighted above, another consideration in the present antenna design is polarization, and thus whether the antenna is capable of sending and receiving signals along one or multiple propagation planes, e.g., horizontal and/or vertical polarization. When there is one aperture slot 106 for each cavity resonator radiator, such as in the embodiment depicted in FIG. 1, the antenna is a single-polarization antenna. See, for instance, FIG. 8 (a cross-sectional view A-A′) and FIG. 9 (a top-down view from viewpoint D in FIG. 8).

For ease and clarity of depiction, only one of the above-described multiple cavity resonator radiators (i.e., a unit cell) is shown in FIG. 8 and FIG. 9. However, it is to be understood that all of the single-element unit cell depictions provided herein are illustrations of radiators that are meant to be in an array. Referring to FIG. 8 and FIG. 9, in this example, each cavity resonator radiator has one aperture slot 106 in ground plane 108, and a corresponding one of the antenna feedlines 104 positioned beneath the aperture slot 106. As described above, each antenna feedline 104 feeds a signal to the cavity resonator radiator via the aperture slot 106.

According to some embodiments, the substrate 102 can also include a ground plane 802 below the (first) dielectric 109. In that case, the terms ‘top’ and ‘bottom’ may also be used herein when referring to ground plane 108 and ground plane 802, respectively. As shown in FIG. 8, ground plane 802 has an opening 804 through which the antenna feedline 104 passes, thereby enabling the antenna feedline 104 to connect to a signal port such as a beamforming integrated circuit (not shown). In this example, the elements 118 along the sidewalls of the cavity resonator radiator have a λ/2 spacing.

In order to highlight the configuration of the aperture slot 106 in ground plane 108 from the top-down, the overlying dielectric 112 is not shown in FIG. 9. Referring to FIG. 9, aperture slot 106 has a rectangular shape and extends along a y-direction. Antenna feedline 104 passes beneath approximately a center of the aperture slot 106. Further, FIG. 9 illustrates the orientation of the cross-sectional cut A-A′ shown in FIG. 8 which is perpendicular to the aperture slot 106.

The present cavity resonator radiator generally has a rectangular shaped cavity with sides of length a and b (see FIG. 9), and a height h (see FIG. 8), and supports discrete frequencies Fᵣₘₙᵢ, each associated with a mode (m, n, l) of the cavity resonator radiator, i.e.,

$${F}_{rmnl} = \frac{150}{\sqrt{{ε}_{r}}} \sqrt{{( \frac{m}{a} )}^{2} + {( \frac{n}{b} )}^{2} + {( \frac{l}{2 h} )}^{2}} ,$$

where frequency F is in gigahertz (GHz), a, b and h are in millimeters (mm), and m=n=l=1. εᵣ is the relative permittivity of dielectric 112 (as compared to a vacuum). In one exemplary embodiment, the present cavity resonator radiator has approximately a square shaped cavity, i.e., where a≈b, which includes a=b, and height h is about λ/4. According to an exemplary, non-limiting embodiment, a≈b denotes that the length a differs from the length b by less than or equal to 0.1λ, where λ is the center frequency of the waveform being transmitted or received. It is notable that, while the design of a≈b may be employed for single polarization, it is not a requirement. Namely, a≈b is primarily for dual-polarization (see immediately below).

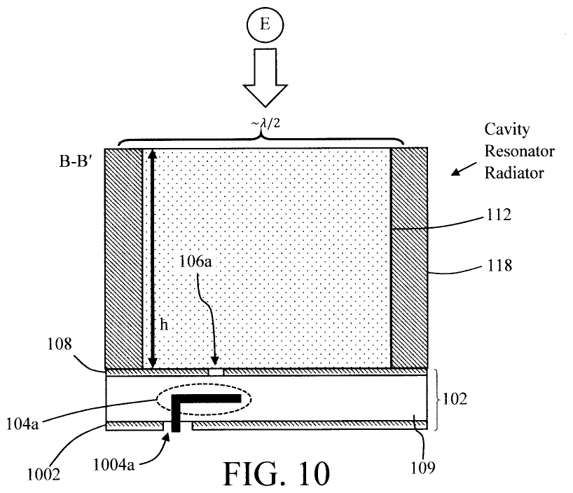

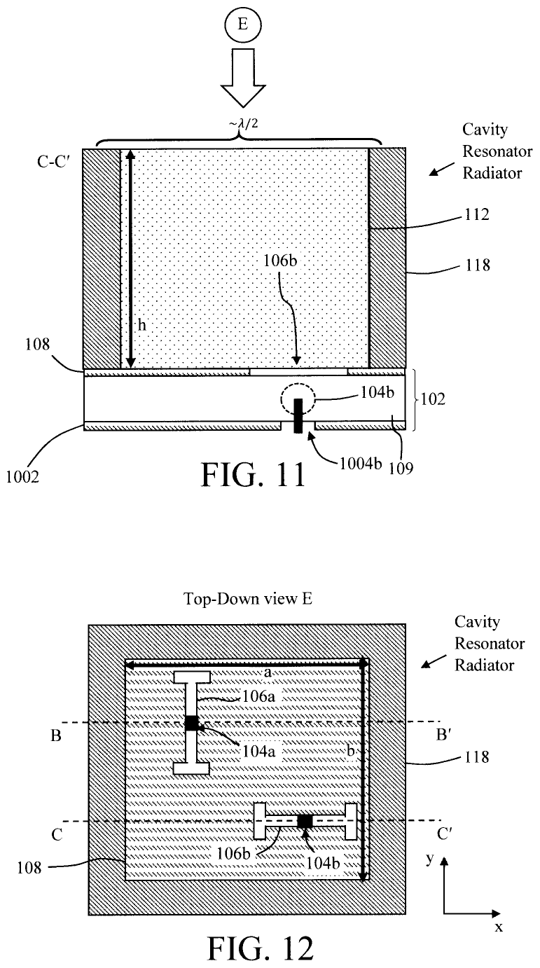

Alternatively, embodiments are also contemplated herein having dual-polarization, where the antenna is capable of sending and receiving signals along multiple propagation planes. See, for instance, FIG. 10 (a cross-sectional view B-B′), FIG. 11 (a cross-sectional view C-C′) and FIG. 12 (a top-down view from viewpoint E in FIGS. 10 and 11).

Again, for ease and clarity of depiction, only one of the above-described multiple cavity resonator radiators (i.e., a unit cell) is shown in FIGS. 10-12. However, as provided above, it is to be understood that all of the single-element unit cell depictions shown herein are illustrations of radiators that are meant to be in an array. Referring to FIGS. 10-12, in this example, each cavity resonator radiator has two aperture slots 106a (see FIG. 10) and 106b (see FIG. 11) in ground plane 108, and corresponding antenna feedlines 104a (see FIG. 10) and 104b (see FIG. 11) positioned beneath the aperture slots 106a and 106b, respectively. For clarity, the terms ‘first’ and ‘second’ may be used when referring to antenna feedlines 104a/aperture slots 106a and antenna feedlines 104b/aperture slots 106b, respectively. As described above, antenna feedline 104a (for vertical polarization) and antenna feedline 104b (for horizontal polarization) feed signals to the cavity resonator radiator via aperture slot 106a and aperture slot 106b, respectively.

In this example, the substrate 102 includes a ground plane 1002 below the (first) dielectric 109. Thus, for clarity, the terms ‘top’ and ‘bottom’ may also be used herein when referring to ground plane 108 and ground plane 1002, respectively. As shown in FIG. 10, ground plane 1002 has an opening 1004a through which the antenna feedline 104a passes, thereby enabling the antenna feedline 104a to connect to a signal port such as a beamforming integrated circuit (not shown). Similarly, as shown in FIG. 11, ground plane 1002 has an opening 1004b through which the antenna feedline 104b passes, thereby enabling the antenna feedline 104b to connect to another signal port such as another beamforming integrated circuit (not shown). In this example, the elements 118 along the sidewalls of the cavity resonator radiator have a λ/2 spacing.

In order to highlight the configuration of the aperture slots 106a and 106b in ground plane 108 from the top-down, the overlying dielectric 112 is not shown in FIG. 11. Referring to FIG. 12, aperture slots 106a and 106b each generally have an ‘H’ shape. Advantageously, an H-shaped aperture slot can be used for dual-polarization designs to reduce the slot length, without the risk of the two aperture slots overlapping one another in the actual design. Namely, the aperture slot length has to be long enough, otherwise the coupling will not strong enough. Aperture slot 106a extends along a y-direction, while aperture slot 106b extends along an x-direction. Antenna feedlines 104a and 104b pass beneath approximately a center of the aperture slots 106a and 106b, respectively. Further, FIG. 12 illustrates the orientation of the cross-sectional cut B-B′ shown in FIG. 10 which is perpendicular to the aperture slot 106a, and that of the cross-sectional cut C-C′ shown in FIG. 11 which is parallel to the aperture slot 106b.

This dual-polarization cavity resonator radiator design can work in transverse electric mode (TE) and, in particular TE11 mode. With TE11 mode, during propagation through a waveguide the electric field and magnetic field are perpendicular to the direction of propagation.

In the dual-polarization example just presented, the antenna feedlines 104a and 104b for vertical and horizontal polarization are located in the same metal layer. In other words, from FIG. 10 and FIG. 11 it can be seen the antenna feedlines 104a and 104b are present side-by-side one another in (first) dielectric 109. However, this close arrangement of the antenna feedlines can potentially lead to poor port isolation.

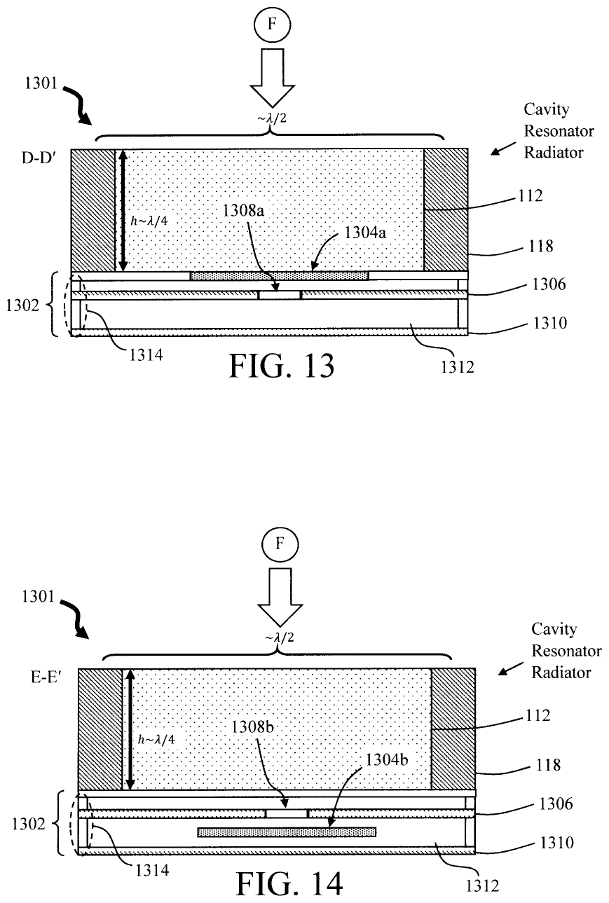

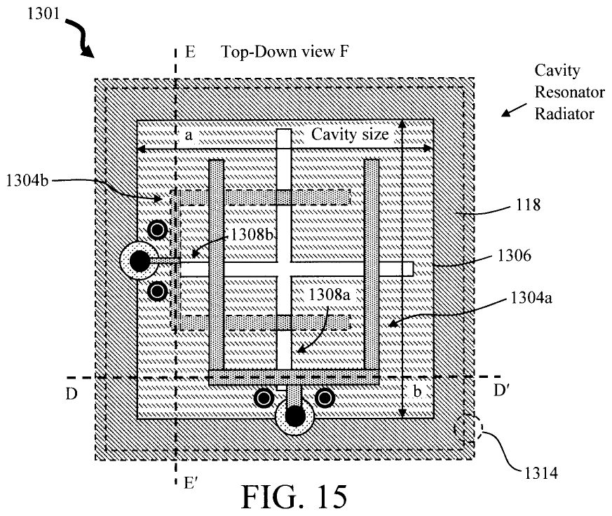

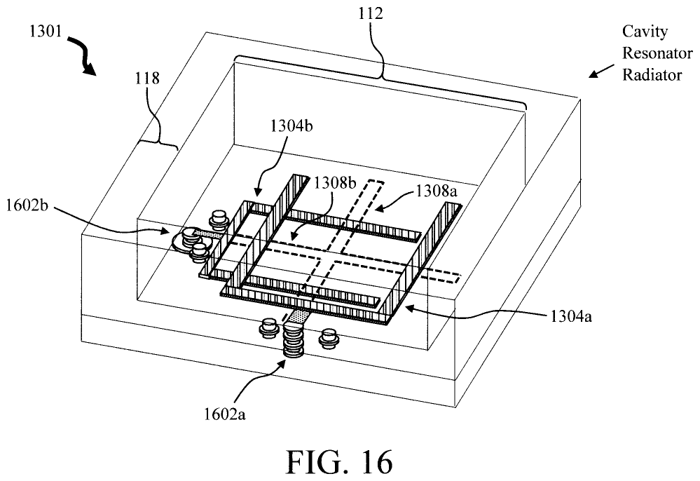

Accordingly, embodiments are also contemplated herein where the vertical and horizontal polarization antenna feedlines are separated from one another in order to enhance port isolation. For instance, in one exemplary embodiment, the vertical polarization antenna feedlines are located above the aperture slots, while the horizontal polarization antenna feedlines are located below the aperture slots, or vice versa. See, for instance, FIG. 13 (a cross-sectional view D-D′), FIG. 14 (a cross-sectional view E-E′), FIG. 15 (a top-down view from viewpoint F in FIGS. 13 and 14) and FIG. 16 (a three-dimensional view).

For ease and clarity of depiction, only one of the above-described multiple cavity resonator radiators (i.e., a unit cell 1301) is shown in FIGS. 13-15. However, as provided above, it is to be understood that all of the single-element unit cell depictions shown herein are illustrations of radiators that are meant to be in an array. In this example, multiple intersecting aperture slots are employed for each cavity resonator radiator for dual-polarization (i.e., vertical and horizontal polarization). Namely, referring to FIGS. 13-15, in the same manner as above, this version of the present phased array antenna device includes a substrate 1302 having (first) antenna feedlines 1304a for vertical polarization (see FIG. 13) and (second) antenna feedlines 1304b for horizontal polarization (see FIG. 14) within a (first) dielectric 1312, and a top ground plane 1306 having a first aperture slot 1308a (see FIG. 13) and a second aperture slot 1308b (see FIG. 14) for each cavity resonator radiator and a bottom ground plane 1310 disposed on the (first) dielectric 1312 (Component I). Coupled to this Component I is the metallic grid having a plurality of cavities filled with the (second) dielectric 112 forming an array of cavity resonator radiators between individual (antenna) elements 118 of the metallic grid (Component II).

The first aperture slot 1308a and second aperture slot 1308b are oriented perpendicular to one another, and in this case intersect one another similar to a ‘+’ symbol (see FIGS. 15 and 16). In order to highlight the configuration of the first and second aperture slots 1308a and 1308b in top ground plane 1306 from the top-down, the overlying dielectric 112 is not shown in FIG. 15. Notably, with this particular placement of the first antenna feedlines 1304a and antenna feedlines 1304b above and below the first/second aperture slots 1308a/1308b, respectively, the vertical polarization and horizontal polarization feedlines are located in different layers. Doing so results in better port isolation. See, e.g., vertical polarization port 1602a and horizontal polarization port 1602b in FIG. 16. Another notable design feature is that substrate 1302 also contains a (metal) ring 1314 that extends from the bottom ground plane 1310 to the bottom of the cavity resonator radiator.

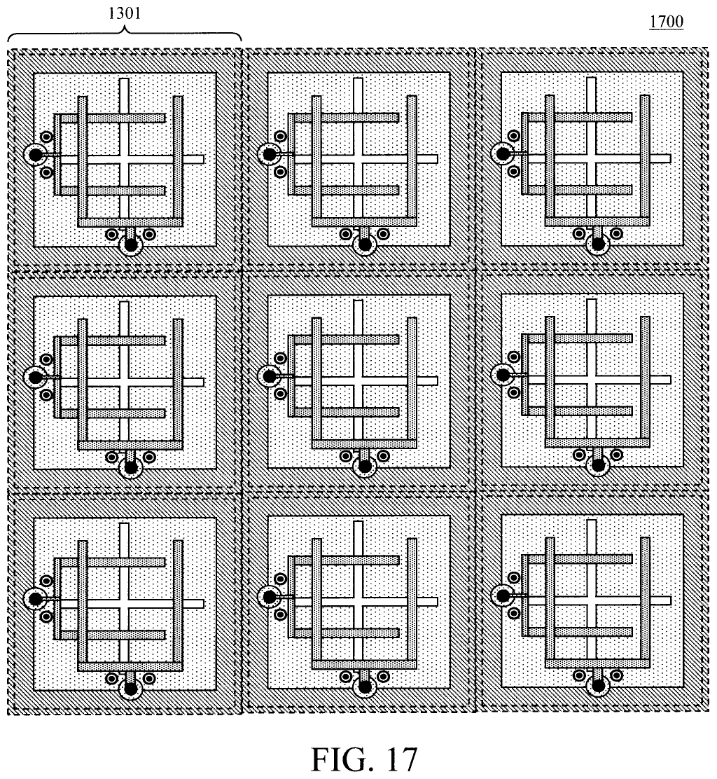

An arrangement of these unit cells 1301 can be implemented as a two-dimensional (2D) array 1700. See FIG. 17. Of course, the number of unit cells 1301 in array 1700 can vary depending on the particular application at hand, with a larger array containing more unit cells 1301 than shown, and vice versa. As described in detail above, each unit cell 1301 in this example has dual (i.e., vertical and horizontal) polarization, with the respective antenna feedlines being located in separated layers in order to improve port isolation. For instance, the vertical and horizontal polarization antenna feedlines can be located above and below the aperture slots, respectively.

In the example described, for instance, in conjunction with the description of FIG. 1 above, solder bumps are used to join beamforming integrated circuits to the antenna feedlines. However, designs are also contemplated herein which integrate arrays of the present cavity resonator radiators at the wafer scale, and which can leverage the benefits of through-via technology. Namely, through-vias provide a high-performance interconnect alternative to traditional wire bonding enabling higher interconnect (and device) density and advantageously shorter connections.

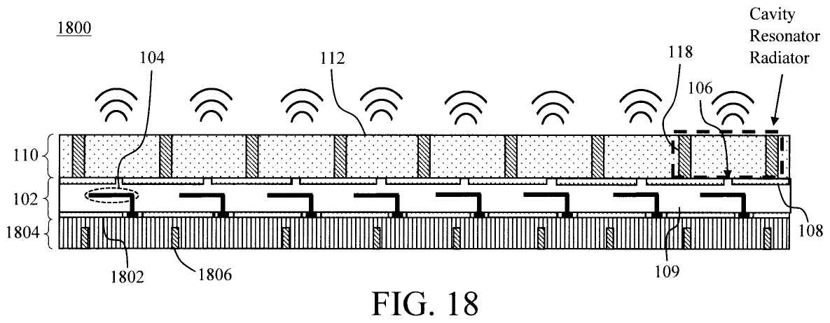

For instance, FIG. 18 depicts a phased array antenna device 1800 in accordance with the present techniques having a wafer 1804 with through-vias 1806. As with the configurations above, phased array antenna device 1800 includes substrate 102 having antenna feedlines 104 within (first) dielectric 109, and (top) ground plane 108 and a (bottom) ground plane 1802 disposed on the (first) dielectric 109, and metallic grid 110 filled with (second) dielectric 112 disposed on the substrate 102. Aperture slots 106 corresponding to the antenna feedlines 104 are present in the (top) ground plane 108. Wafer 1804 may already have pre-built devices (not shown) such as transistors like beamforming integrated circuits, diodes, capacitors and/or resistors, and structures such as interconnects and/or other wiring (not shown) which connect the through-vias 1806 and beamforming integrated circuits to the antenna feedlines 104.

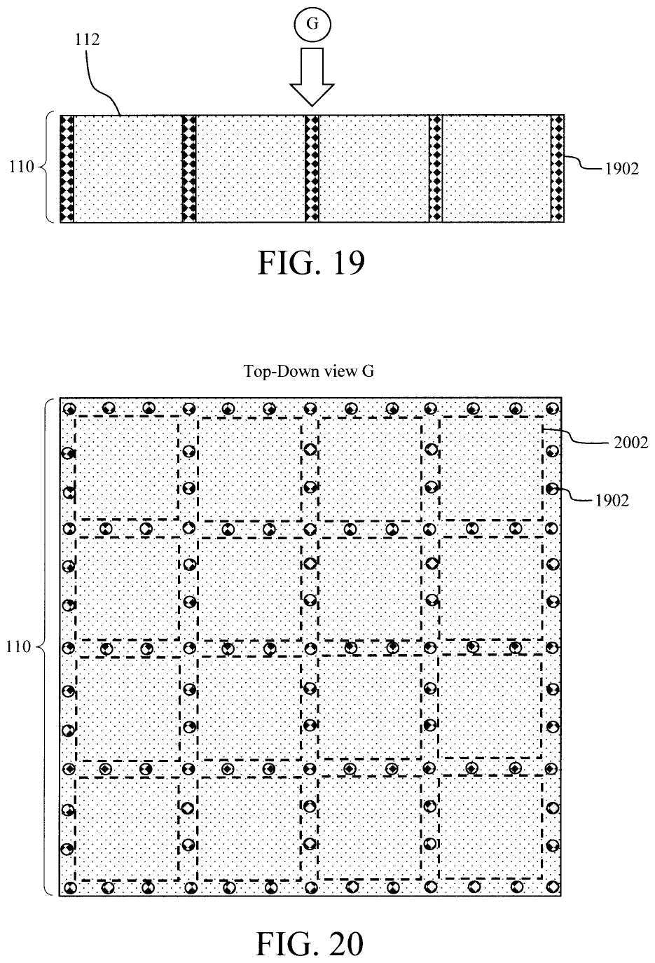

As provided above, 3D printing or other low-complexity manufacturing methods like metal stamping or laser cutting are contemplated herein for simplifying fabrication of the present dielectric filled metallic grid. Another approach contemplated herein is to form the metallic grid from a plurality of metal through vias in the dielectric arranged side-by-side in a grid pattern. See, for instance, FIG. 19 (a cross-sectional view) and FIG. 20 (a top-down view from viewpoint G in FIG. 19).

As shown in FIG. 19, the present metallic grid 110 can be formed from a plurality of metal through vias 1902 in dielectric 112. From the top-down view in FIG. 20, it can be seen that arranging the metal through vias 1902 side-by-side in a grid pattern effectively forms the metallic grid 110 having cavities 2002 filled with the dielectric 112.

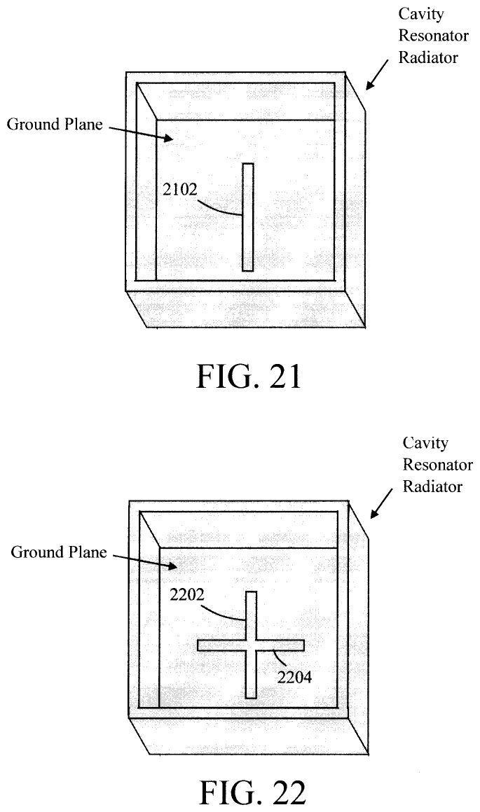

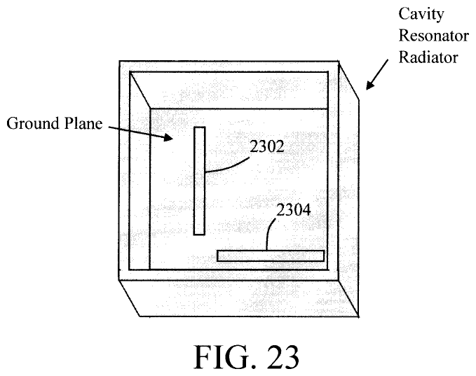

As highlighted above, both single and dual polarization cavity resonator radiator designs are contemplated herein. For single-polarization, the ground plane has one aperture slot for each cavity resonator radiator. See, for example, the three-dimensional representation of a cavity resonator radiator in FIG. 21 having a single aperture slot 2102. For dual-polarization, the ground plane has multiple aperture slots for each cavity resonator radiator. For instance, embodiments are contemplated herein where the aperture slots are oriented perpendicular to one another and intersect one another. See, for example, the three-dimensional representation of a cavity resonator radiator in FIG. 22 having aperture slots 2202 and 2204 that intersect one another similar to a ‘+’ symbol. Embodiments are also contemplated herein where the aperture slots are oriented perpendicular but are spaced apart from one another. See, for example, the three-dimensional representation of a cavity resonator radiator in FIG. 23 having aperture slots 2302 and 2304 that are spaced apart from one another and do not intersect.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. An antenna device, comprising:
a first component comprising a substrate having antenna feedlines within a first dielectric, and a ground plane disposed on the first dielectric;
a second component, coupled to the first component, comprising a metallic grid having a plurality of cavities filled with a second dielectric to provide an array of cavity resonator radiators for the antenna device,
wherein the ground plane comprises aperture slots between the antenna feedlines and the cavity resonator radiators.

2. The antenna device of claim 1, wherein the cavities have a rectangular shape with sides of length a and b, and wherein a≈b.

3. The antenna device of claim 2, wherein a=b.

4. The antenna device of claim 1, wherein sidewalls of each of the plurality of cavities have a spacing of λ/2.

5. The antenna device of claim 1, wherein each of the plurality of cavities has a height h of λ/4.

6. The antenna device of claim 1, wherein the first dielectric has a first dielectric constant κ₁ and the second dielectric has a second dielectric constant κ₂, and wherein the first dielectric constant κ₁ is different from the second dielectric constant κ₂.

7. The antenna device of claim 1, wherein the ground plane comprises at least one of the aperture slots for each of the cavity resonator radiators.

8. The antenna device of claim 7, wherein the ground plane comprises a first aperture slot and a second aperture slot for each of the cavity resonator radiators.

9. The antenna device of claim 8, wherein the first aperture slot is oriented perpendicular to the second aperture slot.

10. The antenna device of claim 9, wherein the first aperture slot intersects the second aperture slot.

11. The antenna device of claim 1, wherein a portion of the second dielectric extends over a top of the metallic grid.

12. The antenna device of claim 1, wherein the antenna feedlines are connected to at least one signal port comprising a beamforming integrated circuit.

13. The antenna device of claim 1, wherein the metallic grid comprises a plurality of metal through vias in the second dielectric arranged side-by-side in a grid pattern.

14. An antenna device, comprising:
a first component comprising a substrate having antenna feedlines within a first dielectric and a ground plane comprising aperture slots disposed on the first dielectric;
a second component, coupled to the first component, comprising a metallic grid having a plurality of cavities filled with a second dielectric to provide an array of cavity resonator radiators for the antenna device,
wherein the antenna feedlines comprise first antenna feedlines and second antenna feedlines for dual-polarization, and wherein the first antenna feedlines and the second antenna feedlines are located in different layers.

15. The antenna device of claim 14, wherein the first antenna feedlines are located above the aperture slots, and wherein the second antenna feedlines are located below the aperture slots.

16. The antenna device of claim 14, wherein the ground plane comprises a first aperture slot and a second aperture slot for each of the cavity resonator radiators, with the first aperture slot being oriented perpendicular to the second aperture slot, and wherein the first aperture slot intersects the second aperture slot.

17. A method of forming an antenna device, the method comprising:
forming a first component comprising a substrate having antenna feedlines within a first dielectric, and a ground plane comprising aperture slots disposed on the first dielectric;
forming a second component comprising a metallic grid having a plurality of cavities filled with a second dielectric to provide an array of cavity resonator radiators; and
joining the first component to the second component such that the aperture slots are present between the antenna feedlines and the cavity resonator radiators to form the antenna device.

18. The method of claim 17, further comprising:
connecting at least one signal port to the antenna feedlines.

19. The method of claim 17, further comprising:
forming the metallic grid having the plurality of cavities filled with the second dielectric using a process selected from the group consisting of: three-dimensional (3D) printing, metal stamping, laser cutting, and combinations thereof.

20. The method of claim 17, further comprising:
forming the metallic grid having the plurality of cavities filled with the second dielectric using mixed metal and dielectric 3D printing.
